(19) United States
(12) Patent Application Publication
(10) Pub. No.: US 2020/0250082 A1
(43) Pub. Date: Aug. 6, 2020

(54) CONTROLLER, MEMORY SYSTEM, AND OPERATING METHOD THEREOF

(71) Applicant: SK hynix Inc., Icheon-si Gyeonggi-do (KR)

(72) Inventor: Bum Seok PARK, Icheon-si Gyeonggi-do (KR)

(73) Assignee: SK hynix Inc., Icheon-si Gyeonggi-do (KR)

(21) Appl. No.: 16/596,366

(22) Filed: Oct. 8, 2019

(30) Foreign Application Priority Data
Feb. 1, 2019 (KR) 10-2019-0013311

(51) Int. Cl. G06F 12/02; G06F 12/0882; G06F 9/30; G06F 9/50; G06F 11/07; G06F 13/16; G11C 11/408

(52) U.S. Cl. CPC G06F 12/0246; G06F 12/0882; G06F 9/30029; G11C 11/4085; G06F 11/076; G06F 13/1668; G06F 9/5016

(57) ABSTRACT

A controller, a memory system, and an operating method of a memory system including a controller are disclosed. A controller configured to control an operation of a memory device including a plurality of data storage regions includes a storage region allocation module configured to allocate a data storage region in which write data is to be stored among the plurality of data storage regions, a data storage reliability determination module configured to determine data storage reliability of an allocated data storage region based on process information of the memory device, a parity management module configured to generate a parity part for the write data based on the data storage reliability, and a control signal generation module configured to generate a control signal for controlling the memory device to store the write data and the parity part in the allocated data storage region.

### CROSS-REFERENCES TO RELATED APPLICATION

The present application claims priority under 35 U.S.C. § 119(a) to Korean application number 10-2019-0013311, filed on Feb. 1, 2019, in the Korean Intellectual Property Office, which is incorporated herein by reference in its entirety.

### BACKGROUND

### 1. Technical Field

Various embodiments generally relate to a semiconductor device, and more particularly, to a controller, a memory system, and an operating method thereof.

### 2. Related Art

In recent years, the paradigm for computer environments changed to ubiquitous computing, which makes use of computer systems everywhere at all times. As a result, use of portable electronic apparatuses, such as mobile phones, digital cameras, and laptop computers, has been increasing rapidly. Generally, portable electronic apparatuses use memory systems that employ memory devices. Memory systems may be used to store data used in the portable electronic apparatuses.

Memory systems using memory devices have no mechanical driving units and exhibit good stability and endurance, fast information access rates, and low power consumption. Such memory systems may include a universal serial bus (USB) memory device, a memory card having various interfaces, a universal flash storage (UFS) device, a solid state drive (SSD), and the like.

### SUMMARY

In an embodiment of the present disclosure, a memory system may include: a memory device including a plurality of data storage regions; and a controller configured to control the memory device. The controller may include: a storage region allocation module configured to allocate at least one data storage region in which write data configured as N (wherein N is a natural number of 2 or more) pieces of sub data is to be stored among the plurality of data storage regions; a data storage reliability determination module configured to determine data storage reliability of an allocated data storage region based on process information of the memory device; a parity management module configured to generate a parity part for the write data every M (wherein M is a natural number larger than 2 and smaller than N) pieces of sub data among the N pieces of sub data by changing the number M of pieces of sub data based on the data storage reliability; and a control signal generation module configured to generate a control signal for controlling the memory device to store the write data and the at least one generated parity part in the allocated data storage region.

In an embodiment of the present disclosure, an operating method of a memory system which includes a memory device configured including a plurality of data storage regions and a controller configured to control an operation of the memory device, the method may include: the controller allocating at least one data storage region in which write data configured as N (wherein N is a natural number of 2 or more) pieces of sub data is to be stored among the plurality of data storage regions; the controller determining data storage reliability of an allocated data storage region based on process information of the memory device; the controller generating a parity part for the write data every M (wherein M is a natural number larger than 2 and smaller than N) pieces of sub data among the N pieces of sub data by changing the number M of pieces of sub data based on the data storage reliability; and the memory device storing the write data and the at least one generated parity part in the allocated data storage region.

In an embodiment of the present disclosure, a memory system may include: a memory device including a plurality of data storage regions; and a controller configured to control the memory device. The controller may include: a data storage reliability determination module configured to determine data storage reliability of at least one data storage region among the plurality of data storage regions based on process information of the memory device; a storage region allocation module configured to allocate a data storage region in which write data configured as N (wherein N is a natural number of 2 or more) pieces of sub data is to be stored based on the data storage reliability; a parity management module configured to generate a parity part for the write data every M (wherein M is a natural number larger than 2 and smaller than N) pieces of sub data among the N pieces of sub data by changing the number M of pieces of sub data based on the data storage reliability; and a control signal generation module configured to generate a control signal for controlling an operation of the memory device to store the write data and the at least one generated parity part in the allocated data storage region.

In an embodiment of the present disclosure, an operating method of a memory system which includes a memory device including a plurality of data storage regions and a controller configured to control an operation of the memory device. The method may include: the controller determining data storage reliability of at least one data storage region among the plurality of data storage regions based on process information received from the memory device; the controller allocating a data storage region in which write data configured as N (wherein N is a natural number of 2 or more) pieces of sub data is to be stored based on the data storage reliability; the controller generating a parity part for the write data every M (wherein M is a natural number larger than 2 and smaller than N) pieces of sub data among the N pieces of sub data by changing the number M of pieces of sub data based on the data storage reliability; the controller controlling the memory device to store the write data and the at least one generated parity part in an allocated data storage region; and the memory device storing the write data and the at least one generated parity part in the allocated data storage region according to control of the controller.

### BRIEF DESCRIPTION OF THE DRAWINGS

The above and other aspects, features, and advantages of the subject matter of the present disclosure will be more clearly understood from the following detailed description taken in conjunction with the accompanying drawings, in which:

FIG. 1 is a diagram illustrating a configuration of a memory system according to an embodiment of the present disclosure;

FIG. 2 is a diagram illustrating a configuration of the memory of FIG. 1;

FIG. 3 is a diagram illustrating a data storage region included in a memory device according to an embodiment of the present disclosure;

FIG. 4 is a block diagram illustrating a flash translation layer (FTL) according to an embodiment of the present disclosure;

FIG. 5 is a flow diagram illustrating an operating method of a memory system according to an embodiment of the present disclosure;

FIG. 6 is a flow diagram illustrating an operating method of a memory system according to an embodiment of the present disclosure;

FIG. 7 is a flow diagram illustrating an operating method of a memory system according to an embodiment of the present disclosure;

FIGS. 8A, 8B, and 8C are diagrams illustrating an example of generating a parity part according to an embodiment of the present disclosure;

FIG. 9 is a block diagram illustrating a data processing system including a solid state drive (SSD) according to an embodiment of the present disclosure;

FIG. 10 is a block diagram illustrating a configuration of the controller in FIG. 9;

FIG. 11 is a diagram illustrating a data processing system including a memory system according to an embodiment of the present disclosure;

FIG. 12 is a diagram illustrating a data processing system including a memory system according to an embodiment of the present disclosure;

FIG. 13 is a diagram illustrating a network system including a memory system according to an embodiment of the present disclosure; and

FIG. 14 is a block diagram illustrating a configuration of a memory device included in a memory system according to an embodiment of the present disclosure.

### DETAILED DESCRIPTION

Various embodiments of the present teachings are described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present teachings as defined in the appended claims.

The present teachings are described herein with reference to cross-section and/or plan illustrations of idealized embodiments. However, described and/or illustrated embodiments of the present teachings should not be construed as limiting the present teachings. Although a few embodiments of the present teachings are shown and described, it will be appreciated by those of ordinary skill in the art that changes may be made in these embodiments without departing from the principles and spirit of the present teachings.

Embodiments are provided to technology capable of improving performance of a memory system based on reliability of a data storage region. According to an embodiment of the present disclosure, the performance of a memory system can be improved based on reliability of a data storage region. These and other features, aspects, and embodiments are described below.

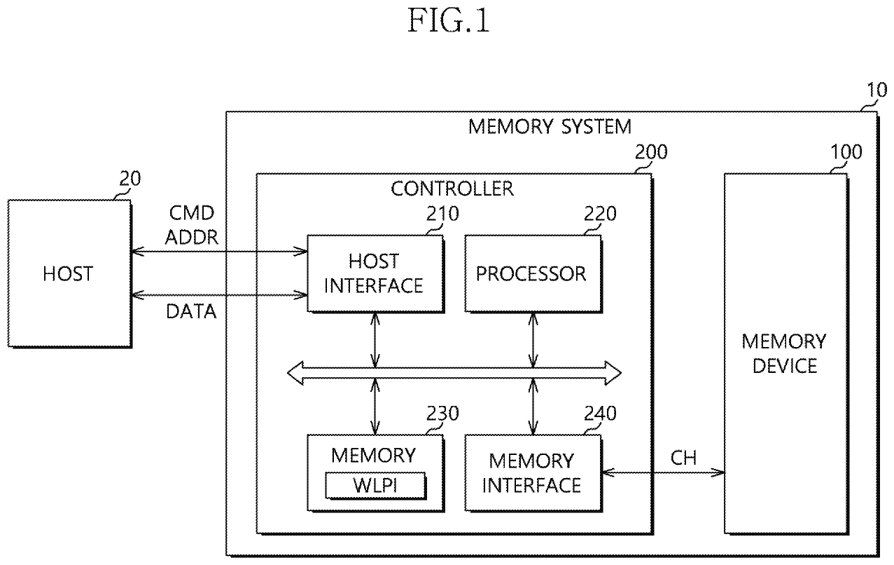

FIG. 1 illustrates a configuration of a memory system 10 according to an embodiment.

Referring to FIG. 1, the memory system 10 may store data to be accessed by a host 20 such as a mobile phone, an MP3 player, a laptop computer, a desktop computer, a game player, a television (TV), an in-vehicle infotainment system, and the like.

The memory system 10 may be manufactured as any one among various types of storage devices according to an interface protocol coupled to the host 20. For example, the memory system 10 may be configured of any one of various types of storage devices, such as: a solid state drive (SSD); a multimedia card in the form of MMC, eMMC, RS-MMC, and micro-MMC; a secure digital card in the form of SD, mini-SD, and micro-SD; a universal serial bus (USB) storage device; a universal flash storage (UFS) device; a personal computer memory card international association (PCMCIA) card type storage device; a peripheral component interconnection (PCI) card type storage device; a PCI-express (PCI-E) card type storage device; a compact flash (CF) card; a smart media card; a memory stick; and the like.

The memory system 10 may be manufactured as any one among various types of packages. For example, the memory system 10 may be manufactured as any one of various types of packages, such as a package on package (POP), a system in package (SIP), a system on chip (SOC), a multi-chip package (MCP), a chip on board (COB), a wafer-level fabricated package (WFP), and a wafer-level stack package (WSP).

The memory system 10 may include a memory device 100 and a controller 200.

The memory device 100 may be operated as a storage medium of the memory system 10. The memory device 100 may be a volatile memory device or a nonvolatile memory device. The memory device 100 may include any one of various types of memory devices according to a memory cell, such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase-change random access memory (PRAM) using a chalcogenide alloy, and a resistive random access memory (ReRAM) using a transition metal compound.

Although FIG. 1 specifically illustrates that the memory system 10 includes one memory device 100 for clarity, the memory system 10 may include a plurality of memory devices and the present disclosure may be equally applied to the memory system 10 including the plurality of memory devices.

The memory device 100, to be described in detail later with reference to FIG. 14, may include a memory cell array 110 including a plurality of memory cells MC arranged in regions in which a plurality of word lines WL1 to WLm and a plurality of bit lines BL1 to BLn cross each other. The memory cell array 110 may include a plurality of memory blocks and each of the plurality of memory blocks may include a plurality of pages.

For example, each of the memory cells in the memory cell array 110 may be a single-level cell (SLC) in which a single bit of data (for example, 1-bit data) is stored or a multi-level cell (MLC) in which two or more bits of data are stored. The MLC may store 2-bit data, 3-bit data, 4-bit data, etc. More specifically, a memory cell in which 2-bit data is stored is a MLC, a memory cell in which 3-bit data is stored is a triple-level cell (TLC), and a memory cell in which 4-bit data is stored is a quadruple-level cell (QLC). However, for clarity, the memory cells in which 2-bit to 4-bit data is stored may collectively be referred to as MLCs.

The memory cell array 110 may include at least one or more SLCs and MLCs. The memory cell array 110 may include memory cells arranged in a two-dimensional (2D) horizontal structure or in a 3D vertical structure.

The controller 200 may control an overall operation of the memory system 10 through driving firmware or software loaded into memory 230. The controller 200 may decode and drive a code-type instruction or algorithm such as firmware or software. The controller 200 may be implemented with hardware or a combination of hardware and software.

The controller 200 may include a host interface 210, a processor 220, the memory 230, and a memory interface 240. Although not shown in FIG. 1, the controller 200 may further include an error correction code (ECC) engine which generates a parity part by ECC encoding write data provided from the host 20 and ECC decodes read data read out from the memory device 100 using the parity part. The host interface 210 may perform interfacing between the host 20 and the memory system 10 according to a protocol of the host 20. For example, the host interface 210 may communicate with the host 20 through any one protocol among a USB protocol, a UFS protocol, an MMC protocol, a parallel advanced technology attachment (PATA) protocol, a serial advanced technology attachment (SATA) protocol, a small computer system interface (SCSI) protocol, a serial attached SCSI (SAS) protocol, a PCI protocol, and a PCI-E protocol.

The processor 220 may be configured as a micro control unit (MCU) and a central processing unit (CPU). The processor 220 may process requests transmitted from the host 20. To process a request transmitted from the host 20, the processor 220 may drive a code-type instruction or algorithm (for example, firmware) loaded into the memory 230 and control internal function blocks such as the host interface 210, the memory 230, and the memory interface 240 and the memory device 100.

The processor 220 may generate control signals for controlling operations of the memory device 100 based on the requests transmitted from the host 20 and provide the generated control signals to the memory device 100 through the memory interface 240.

The memory 230 may be configured as random access memory such as dynamic random access memory (DRAM) or static random access memory (SRAM). The memory 230 may store the firmware driven through the processor 220. The memory 230 may also store data (for example, metadata) required for driving of the firmware. For example, the memory 230 may be operated as working memory of the processor 220.

The memory 230 may be configured to include a data buffer configured to temporarily store write data to be transmitted to the memory device 100 from the host 20 or read data to be transmitted to the host 20 from the memory device 100. For example, the memory 230 may be operated as buffer memory of the processor 220.

The memory interface 240 may control the memory device 100 according to control of the processor 220. The memory interface 240 may refer to a memory controller. The memory interface 240 may provide control signals to the memory device 100. The control signals may include a command, an address, and an operation control signal, and the like for controlling the memory device 100. The memory interface 240 may provide data stored in the data buffer to the memory device 100 or store data transmitted from the memory device 100 in the data buffer.

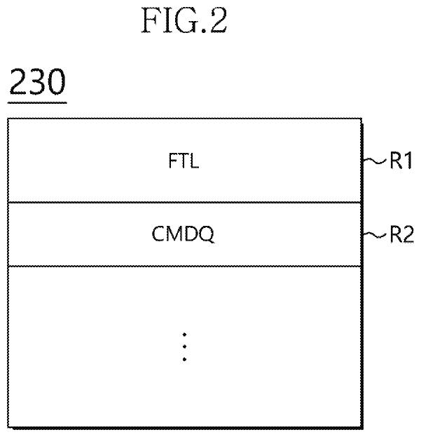

FIG. 2 is a diagram illustrating a configuration of the memory 230 of FIG. 1.

Referring to FIG. 2, the memory 230 may include a first region R1 in which a flash translation layer FTL is to be stored, a second region R2 used as a command queue CMDQ for queuing commands corresponding to requests provided from the host 20, and the like. The memory 230 may further include, in addition to the regions R1 and R2 illustrated in FIG. 2, regions used for various purposes such as a region used as a write data buffer in which write data is temporarily stored, a region used as a read data buffer in which read data is temporarily stored, and a region used as a map cache buffer in which map data is cached.

The memory 230 may include a region (not shown) in which system data, metadata, and the like are stored. Workload pattern information WLPI, shown in FIG. 1, may be stored in the region of the memory 230 in which the system data, metadata, and the like are stored.

When the memory device 100 is configured as a flash memory device, the processor 220 may control an intrinsic operation of the memory device 100 and drive software called the flash translation layer FTL to provide device compatibility with the host 20. The host 20 may recognize and use the memory system 10 as a general storage device such as a hard disc through the driving of the flash translation layer FTL.

The flash translation layer FTL stored in the first region R1 of the memory 230 may include modules configured to perform various functions and metadata used for driving the modules. The flash translation layer FTL may be stored in a system region (not shown) of the memory device 100 and when the memory system 10 is powered on, the flash translation layer FTL may be read out from the system region of the memory device 100 and loaded to the first region R1 of the memory 230.

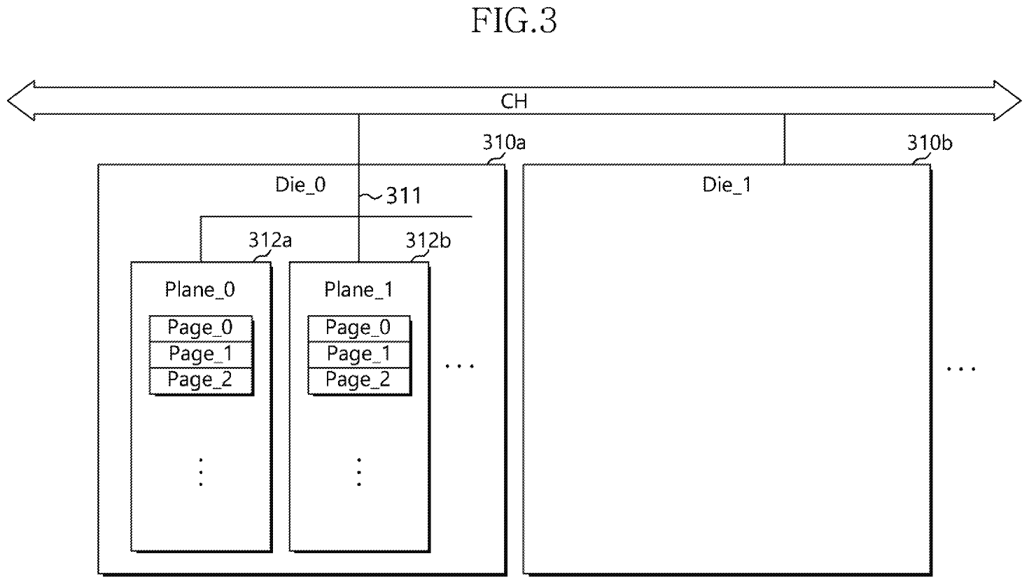

FIG. 3 is a diagram illustrating a data storage region included in a memory device according to an embodiment.

Referring to FIG. 3, the memory device 100 may include a plurality of dies (Die_0 and Die_1) 310a and 310b which share a channel CH coupled to the controller 200. Each of the dies 310a and 310b may include a plurality of planes 312a and 312b which share a way 311 coupled to the channel CH, and each of the planes 312a and 312b may include a plurality of pages Page_0, Page_1, Page_2, . . . . Here, a page may refer to a minimum unit of storage for writing or reading data. Further, a plurality of page units on which an erase operation is collectively performed may refer to a block, and a plurality of block units integrally managed may refer to a super block. A die may refer to a memory chip.

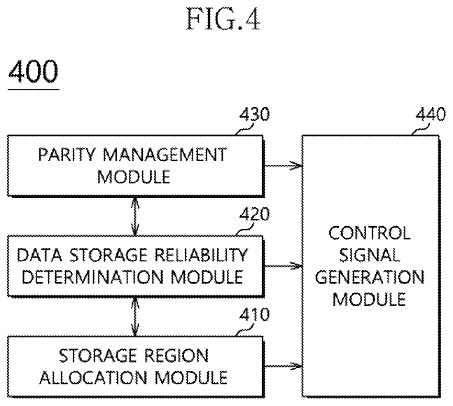

FIG. 4 is a block diagram illustrating a flash translation layer (FTL) 400 according to an embodiment.

Referring to FIG. 4, the flash translation layer 400 may include a storage region allocation module 410, a data storage reliability determination module 420, a parity management module 430, and a control signal generation module 440.

The storage region allocation module 410 may allocate a data storage region in which write data is stored among a plurality of data storage regions included in the memory device 100.

In an embodiment, the write data may be configured as a plurality of pieces of sub data, for example, N (wherein N is a natural number of 2 or more) pieces of sub data.

In an embodiment, the storage region allocation module 410 may allocate a data storage region in which data is not stored among the plurality of data storage regions included in the memory device 100 as the data storage region in which the write data is to be stored. For example, the storage region allocation module 410 may allocate a block in which the write data is to be stored among available open blocks of the memory device 100.

The storage region allocation module 410 may allocate the data storage region in which the write data is to be stored based on data storage reliability.

In an embodiment, the storage region allocation module 410 may preferentially allocate a data storage region having high data storage reliability among a plurality of available data storage regions.

In an embodiment, the storage region allocation module 410 may allocate the data storage region based on data attributes. For example, the storage region allocation module 410 may allocate a data storage region having high data storage reliability with respect to high-scored write data (for example, system data and the like). The storage region allocation module 410 may allocate a data storage region having the relatively low data storage reliability with respect to low-scored write data (for example, user data and the like).

The data storage reliability determination module 420 may determine the data storage reliability of the data storage region. For example, the data storage reliability determination module 420 may determine the data storage reliability of the data storage regions included in the memory device 100 based on process information of the memory device 100.

Here, the data storage reliability may refer to the degree that data loss does not occurs in processes of storing data in the data storage region, retaining data stored in the data storage region, reading data read from the data storage region, and the like.

In an embodiment, the data storage reliability may be determined according to a criterion or criteria, or may be relatively determined between the data storage regions.

Process information may refer to any information that may affect the data storage reliability among information obtained in the fabrication process of the memory device 100.

In an embodiment, the process information may refer to position information of a memory chip on a wafer. For example, as a position of a data storage region of a memory chip, a plane, or the like on the wafer used in a process of fabricating the memory device 100 is away from the center of the wafer, the data storage reliability determination module 420 may determine the data storage reliability of the data storage region to be low. This is because a failure rate at an edge of the wafer is generally high. In another example, when a position of a data storage region of a memory chip, a plane, or the like on a wafer used in a process of fabricating the memory device 100 corresponds to an area having a high failure rate of the corresponding process, then the data storage reliability determination module 420 may determine the data storage reliability of the data storage region to be low. This is because a specific area having a high failure rate may be present every process equipment for fabricating the memory device 100. Accordingly, the data storage reliability determination module 420 may determine the data storage reliability of the data storage region present in the area having the high failure rate on the wafer to be low.

In an embodiment, the process information may refer to position information of the data storage region in a plane, a super block, a block, and the like on a memory chip. For example, as the data storage region of the plane, or the like is located close to an edge of a memory chip, the data storage reliability determination module 420 may determine the data storage reliability of the data storage region to be low. In general, this is because the failure rate of the data storage region located at the edge of the memory chip is high in general.

In an embodiment, the process information may refer to information of a word line coupled to a page. For example, when a plurality of pages are included in one block and a word line is coupled to each of the plurality of pages, the data storage reliability determination module 420 may determine the data storage reliability of the data storage regions to be different from each other according to the information of the word lines of the pages. The information of the word line may indicate that each of the word lines is located in any one of an upper portion, a central potion, and a lower portion of the block. For example, when the failure rate of an upper word line of the block is high, the data storage reliability determination module 420 may determine the data storage reliability of the page coupled to the upper word line to be low.

In an embodiment, the process information may be stored in the memory device 100. For example, the process information may be stored in the memory device during a fabrication stage or a use stage of the memory device. The data storage reliability determination module 420 may receive the process information stored in the memory device from the memory device when determining the data storage reliability is necessary. The data storage reliability determination module may determine the data storage reliability of the data storage region using the process information received from the memory device.

In an embodiment, the data storage reliability determination module 420 may determine the data storage reliability of the data storage region in advance or may determine the data storage reliability of the data storage region when data needs to be stored, for example, when a command is received from the host 20. Further, the data storage reliability determination module 420 may perform an operation of determining the data storage reliability of the data storage region with a background or foreground.

In an embodiment, the data storage reliability determination module 420 may determine the data storage reliability of the data storage region allocated as the data storage region in which the write data is to be stored.

The data storage reliability determination module 420 may determine the data storage reliability based on the results of performing tests (for example, data write tests, data read tests, and the like) on the plurality of data storage regions included in the memory device 100.

The data storage reliability determination module 420 may determine the data storage reliability based on wear-leveling information of the data storage region according to the use of the memory system 10. For example, the data storage reliability determination module 420 may determine the data storage reliability of a data storage region, subjected to a large number of data write and erase operations, to be low.

The parity management module 430 may generate and manage at least one a parity part for the write data based on the data storage reliability.

When the write data is configured as N (wherein N is a natural number of 2 or more) pieces of sub data, the parity management module 430 may generate one parity part every M (wherein M is a natural number larger than 2 and smaller than N) pieces of sub data among the N pieces of sub data.

In an embodiment, the parity management module 430 may change the number M of pieces of sub data for generating the parity part according to the data storage reliability. For example, the parity management module 430 may change the number M of pieces of sub data to be reduced when the data storage reliability is high and may change the number M of pieces of sub data to be increased when the data storage reliability is low.

In an embodiment, the parity management module 430 may generate the parity part by performing an exclusive OR (XOR) operation on M pieces of sub data.

In an embodiment, the parity management module 430 may determine the data storage region in which the parity part is to be stored among the plurality of data storage regions included in the memory device 100. For example, the parity management module 430 may determine the data storage region so that the parity part is stored in the same block as the block in which the write data is to be stored.

In an embodiment, the parity management module 430 might not generate the parity part when the data storage reliability of the allocated data storage region is high.

The control signal generation module 440 may generate a control signal for controlling the memory device 100. For example, the control signal generation module 440 may generate a signal for controlling an operation of the memory device 100 to store the write data in the allocated data storage region and transmit the generated signal to the memory device 100. Accordingly, the memory device 100 may store the write data, the parity part, and the like in the allocated data storage region.

The firmware included in the flash translation layer FTL which allows the operation of the memory system 10 to be performed is divided and described according to a functional aspect. However, embodiments are not limited to software such as the firmware and the flash translation layer (FTL) may be configured of separate hardware components, such as a circuit and the like.

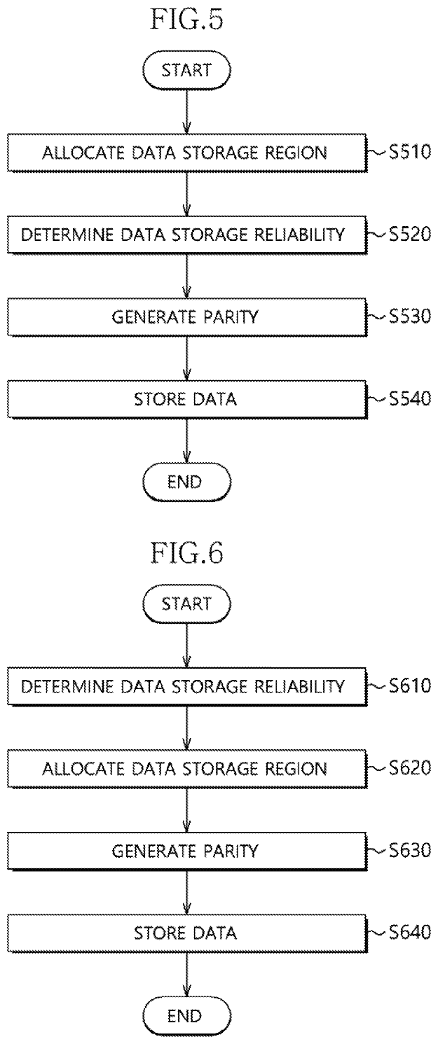

FIG. 5 is a diagram illustrating an operating method of a memory system according to an embodiment.

The operating method described below and illustrated in FIG. 5 relates to an operation example of the memory system 10 illustrated in FIG. 1 and thus the detailed description for FIGS. 1 to 4 may be applied to the method illustrated in FIG. 5.

Referring to FIG. 5, in operation S510, a data storage region may be allocated. For example, the memory system 10 may allocate a data storage region in which write data is to be stored among the plurality of data storage regions included in the memory device 100.

In operation S520, data storage reliability may be determined. For example, the memory system 10 may determine the data storage reliability of the allocated data storage region based on process information of the memory device 100.

In operation S530, a parity part for the write data may be generated. For example, the memory system 10 may generate the parity part for the write data based on the data storage reliability of the allocated data storage region.

In operation S540, the write data may be stored. For example, the memory system 10 may store the write data in the allocated data storage region. Further, the memory system 10 may store the parity part in the data storage region stored with the write data.

FIG. 6 is a diagram illustrating an operating method of a memory system according to an embodiment.

The operating method described below and illustrated in FIG. 6 relates to an operation example of the memory system 10 illustrated in FIG. 1 and thus the detailed description for FIGS. 1 to 5 may be applied to the method illustrated in FIG. 6.

Referring to FIG. 6, in operation S610, data storage reliability may be determined. For example, the memory system 10 may determine the data storage reliability of a plurality of data storage regions included in the memory device 100 based on process information of the memory device 100.

In operation S620, a data storage region in which write data is to be stored may be allocated. For example, the memory system 10 may allocate data storage regions having different data storage reliability from each other according to attributes of data.

In an embodiment, when the write data is high-scored data (for example, system data and the like), the memory system 10 may allocate a data storage region having high data storage reliability as the data storage region in which the write data is to be stored.

In an embodiment, when the write data is low-scored data (for example, user data and the like), the memory system 10 may allocate a data storage region having relatively low data storage reliability as the data storage region in which the write data is to be stored.

In operation S630, a parity part for the write data may be generated. For example, the memory system 10 may generate the parity part for the write data based on the data storage reliability of the allocated data storage region.

In operation S640, the write data may be stored. For example, the memory system 10 may store the write data in the allocated data storage region. Further, the memory system 10 may store the parity part in the data storage region stored with the write data.

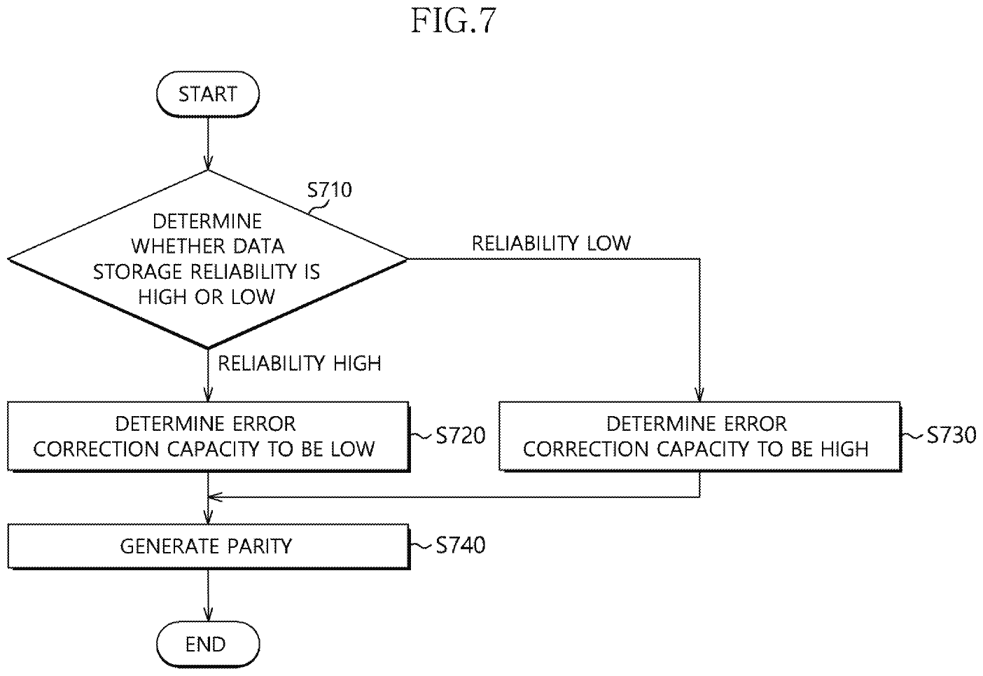

FIG. 7 is a diagram illustrating an operating method of a memory system according to an embodiment.

The operating method described below and illustrated in FIG. 7 relates to an operation example of the memory system 10 illustrated in FIG. 1 and thus the detailed description for FIGS. 1 to 6 may be applied to the method illustrated in FIG. 7.

Referring to FIG. 7, in operation S710, the memory system 10 may determine whether data storage reliability of an allocated data storage region is high or low. For example, the memory system 10 may determine whether the data storage reliability of the allocated data storage region is high or low based on process information of the memory device 100.

In operation S720, error correction capacity may be determined to be low. For example, when the data storage reliability of the allocated data storage region is high as a determination result in operation S710, the memory system 10 may determine the number of pieces of write data, which is included in a write data group, for generating a parity part for the write data to be increased.

In operation S730, the error correction capacity may be determined to be high. For example, when the data storage reliability of the allocated data storage region is low as the determination result in operation S710, the memory system 10 may determine the number of pieces of write data, which is included in the write data group, for generating a parity part for the write data to be reduced.

In operation S740, a parity part of the write data may be generated. For example, the memory system 10 may generate the parity part by performing an XOR operation on the write data included in the write data group including the determined number of pieces of write data.

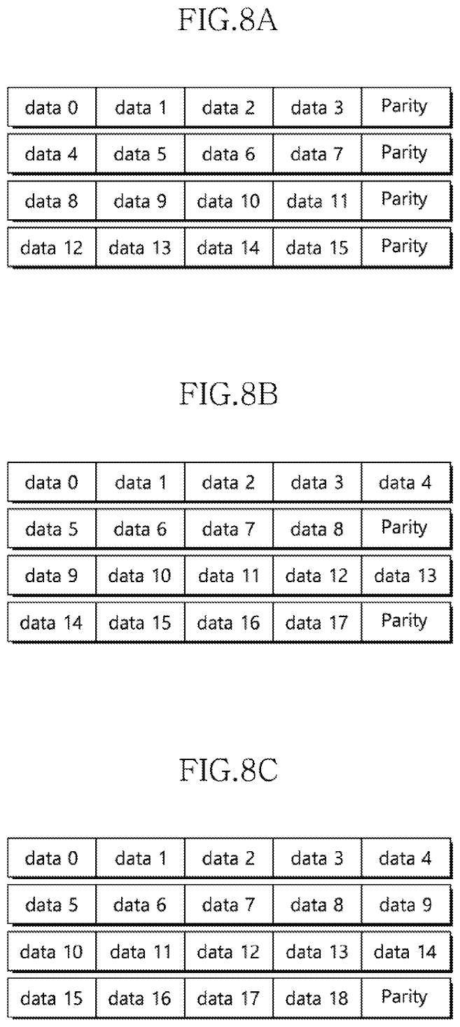

FIG. 8 is a diagram illustrating the generation of parity parts according to an embodiment. FIG. 8 illustrates individual pieces of sub data (e.g., data 0, data 1, data 3, . . . ) and parity parts (Parity). Sub data, for example, represents write data discretized into a finite number of pieces. The pieces of sub data the write data is discretized into (i.e., configured as) may be defined by memory size or by memory location in one or more memory devices. A parity part, for example, represents a discretized portion of memory, based on either size or location, associated with a number (i.e., a number N) of sub data pieces.

Referring to FIGS. 8A, 8B, and 8C, an example of generating parity parts according to data storage reliability of a data storage region is illustrated. The parity generation example is described below based on the assumption that the data storage reliability of the data storage region illustrated in FIGS. 8A, 8B, and 8C increases in the order FIG. 8A<FIG. 8B<FIG. 8C.

In FIG. 8A, the memory system 10 may generate one parity part every 4 pieces of sub data. For example, the memory system 10 may generate a first parity part by performing an XOR operation on sub data 0 data 0 to sub data 3 data 3. In the example of FIG. 8A, because one parity part is generated every 4 pieces of sub data, error-occurred data may be recovered based on the remaining three pieces of sub data and the parity part when an error occurs in any one of the 4 pieces of sub data and thus the error correction capacity may be increased. However, because one parity part is generated and stored every 4 pieces of sub data, the performance of the memory system 10 may be degraded.

In FIG. 8B, the memory system 10 may generate one parity part every 9 pieces of sub data. For example, the memory system 10 may generate a first parity part by performing an XOR operation on sub data 0 data 0 to sub data 8 data 8. In the example of FIG. 8B, because one parity part is generated every 9 pieces of sub data, the error correction capacity may be relatively lowered as compared with the example of FIG. 8A, but the performance of the memory system 10 may be less degraded as compared with the example of FIG. 8A.

In FIG. 8C, the memory system 10 may generate one parity part every 19 pieces of sub data. For example, the memory system 10 may generate a first parity part by performing an XOR operation on sub data 0 data 0 to sub data 18 data 18. In the example of FIG. 8C, because one parity part is generated every 19 pieces of sub data, the error correction capacity may be relatively lowered as compared with the example of FIG. 8B, but the performance of the memory system 10 may be less degraded as compared with the example of FIG. 8B.

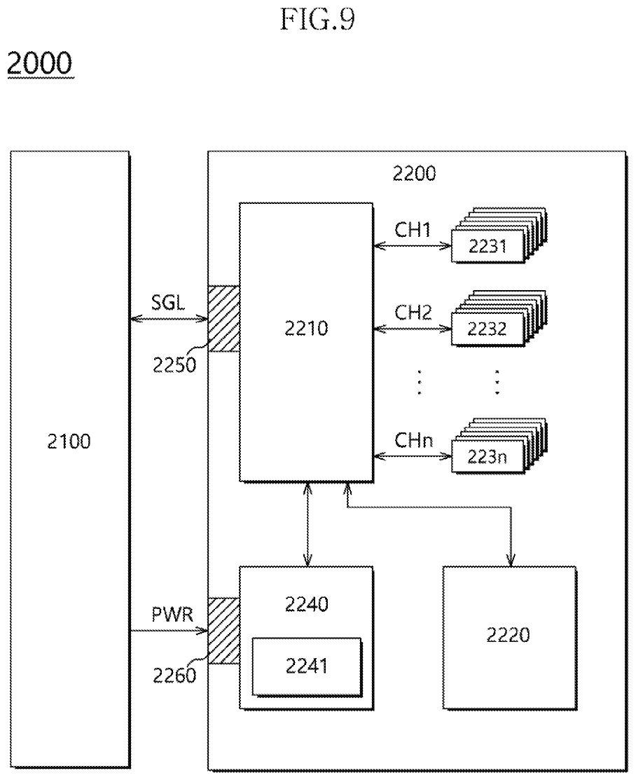

FIG. 9 is a block diagram illustrating a data processing system 2000 including a solid state drive (SSD) 2200 according to an embodiment. Referring to FIG. 9, the data processing system 2000 may include a host 2100 and the solid state drive (SSD) 2200.

The SSD 2200 may include a controller 2210, a buffer memory device 2220, memory devices 2231 to 223n, a power supply 2240, a signal connector 2250, and a power connector 2260.

The controller 2210 may control an overall operation of the SSD 2200.

The buffer memory device 2220 may temporarily store data which are to be stored in the memory devices 2231 to 223n. Further, the buffer memory device 2220 may temporarily store data which are read out from the memory devices 2231 to 223n. The data temporarily stored in the buffer memory device 2220 may be transmitted to the host 2100 or the memory devices 2231 to 223n according to control of the controller 2210.

The memory devices 2231 to 223n may be used as storage media of the SSD 2200. The memory devices 2231 to 223n may be coupled with the controller 2210 through a plurality of channels CH1 to CHn, respectively. One or more memory devices may be coupled to one channel. The memory devices coupled to one channel may be coupled to the same signal bus and data bus.

The power supply 2240 may provide power PWR inputted through the power connector 2260 to the inside of the SSD 2200. The power supply 2240 may include an auxiliary power supply 2241. The auxiliary power supply 2241 may supply power to allow the SSD 2200 to be normally terminated when sudden power-off (SPO) occurs. The auxiliary power supply 2241 may include large capacity capacitors capable of charging the power PWR.

The controller 2210 may exchange a signal SGL with the host 2100 through the signal connector 2250. The signal SGL may include a command, an address, data, and the like. The signal connector 2250 may be configured of various types of connectors according to an interface scheme between the host 2100 and the SSD 2200.

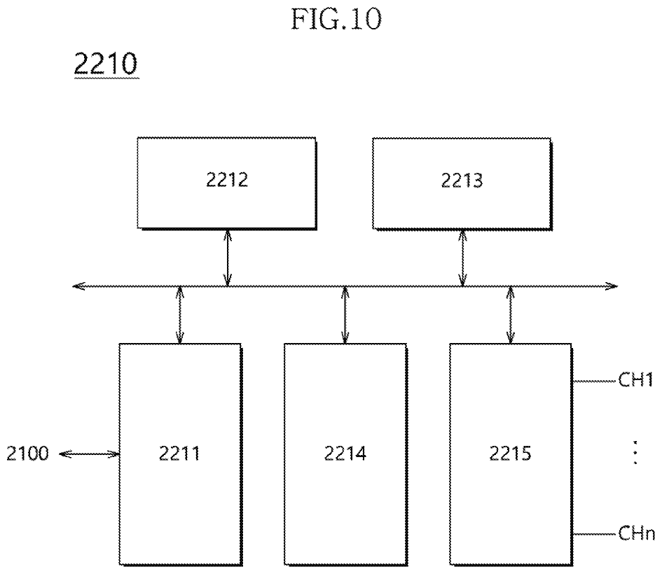

FIG. 10 is a block diagram illustrating the controller 2210 shown in FIG. 9. Referring to FIG. 10, the controller 2210 may include a host interface unit 2211, a control unit 2212, a random access memory (RAM) 2213, an error correction code (ECC) unit 2214, and a memory interface unit 2215.

The host interface unit 2211 may provide interfacing between the host 2100 and the SSD 2200 according to a protocol of the host 2100. For example, the host interface unit 2211 may communicate with the host 2100 through any one among SD, USB, MMC, embedded MMC (eMMC), PCMCIA, PATA, SATA, SCSI, SAS, PCI, PCI-E, and UFS protocols. In addition, the host interface unit 2211 may perform a disk emulating function of supporting the host 2100 to recognize the SSD 2200 as a general-purpose memory system, for example, a hard disk drive (HDD).

The control unit 2212 may analyze and process the signals SGL inputted from the host 2100. The control unit 2212 may control operations of internal function blocks according to firmware or software for driving the SSD 2200. The RAM 2213 may be used as a working memory for driving such firmware or software.

The ECC unit 2214 may generate parity data of data to be transmitted to the memory devices 2231 to 223n. The generated parity data may be stored, along with the data, in the memory devices 2231 to 223n. The ECC unit 2214 may detect errors of data read out from the memory devices 2231 to 223n based on the parity data. When the detected errors are within a correctable range, the ECC unit 2214 may correct the detected errors.

The memory interface unit 2215 may provide control signals such as commands and addresses to the memory devices 2231 to 223n according to control of the control unit 2212. The memory interface unit 2215 may exchange data with the memory devices 2231 to 223n according to control of the control unit 2212. For example, the memory interface unit 2215 may provide data stored in the buffer memory device 2220 to the memory devices 2231 to 223n or provide data read out from the memory devices 2231 to 223n to the buffer memory device 2220.

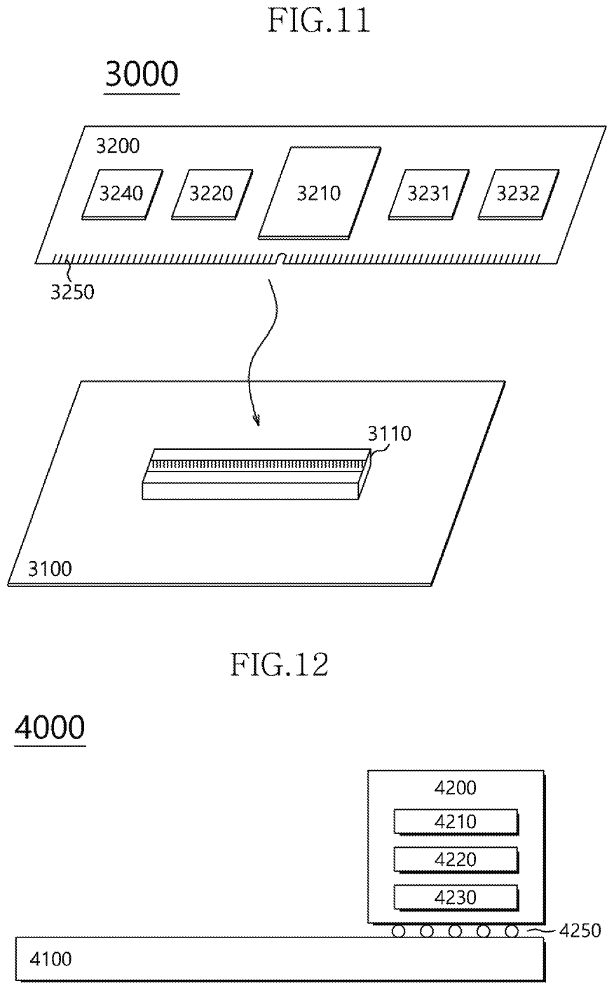

FIG. 11 is a diagram illustrating a data processing system 3000 including a memory system 3200 according to an embodiment. Referring to FIG. 11, the data processing system 3000 may include a host 3100 and the memory system 3200.

The host 3100 may be configured in the form of a board such as a printed circuit board. Although not shown in FIG. 11, the host 3100 may include internal function blocks for performing functions of the host.

The host 3100 may include a connection terminal 3110 such as a socket, a slot, or a connector. The memory system 3200 may be mounted on the connection terminal 3110.

The memory system 3200 may be configured in the form of a board such as a printed circuit board. The memory system 3200 may refer to a memory module or a memory card. The memory system 3200 may include a controller 3210, a buffer memory device 3220, memory devices 3231 and 3232, a power management integrated circuit (PMIC) 3240, and a connection terminal 3250.

The controller 3210 may control an overall operation of the memory system 3200. The controller 3210 may be configured in the same manner as the controller 2210 shown in FIG. 10.

The buffer memory device 3220 may temporarily store data to be stored in the memory devices 3231 and 3232. Further, the buffer memory device 3220 may temporarily store data read out from the memory devices 3231 and 3232. The data temporarily stored in the buffer memory device 3220 may be transmitted to the host 3100 or the memory devices 3231 and 3232 according to control of the controller 3210.

The memory devices 3231 and 3232 may be used as storage media of the memory system 3200.

The PMIC 3240 may provide power inputted through the connection terminal 3250, to the inside of the memory system 3200. The PMIC 3240 may manage the power of the memory system 3200 according to control of the controller 3210.

The connection terminal 3250 may be coupled to the connection terminal 3110 of the host 3100. Through the connection terminal 3250, signals such as commands, addresses, data, and the like and power may be transferred between the host 3100 and the memory system 3200. The connection terminal 3250 may be configured in various types depending on an interface scheme between the host 3100 and the memory system 3200. The connection terminal 3250 may be disposed on any one side of the memory system 3200.

FIG. 12 is a block diagram illustrating a data processing system 4000 including a memory system 4200 according to an embodiment. Referring to FIG. 12, the data processing system 4000 may include a host 4100 and the memory system 4200.

The host 4100 may be configured in the form of a board such as a printed circuit board. Although not shown in FIG. 12, the host 4100 may include internal function blocks for performing functions of the host.

The memory system 4200 may be configured in the form of a surface-mounting type package. The memory system 4200 may be mounted on the host 4100 through solder balls 4250. The memory system 4200 may include a controller 4210, a buffer memory device 4220, and a memory device 4230.

The controller 4210 may control an overall operation of the memory system 4200. The controller 4210 may be configured in the same manner as the controller 2210 shown in FIG. 10.

The buffer memory device 4220 may temporarily store data to be stored in the memory device 4230. Further, the buffer memory device 4220 may temporarily store data read out from the memory device 4230. The data temporarily stored in the buffer memory device 4220 may be transmitted to the host 4100 or the memory device 4230 according to control of the controller 4210.

The memory device 4230 may be used as a storage medium of the memory system 4200.

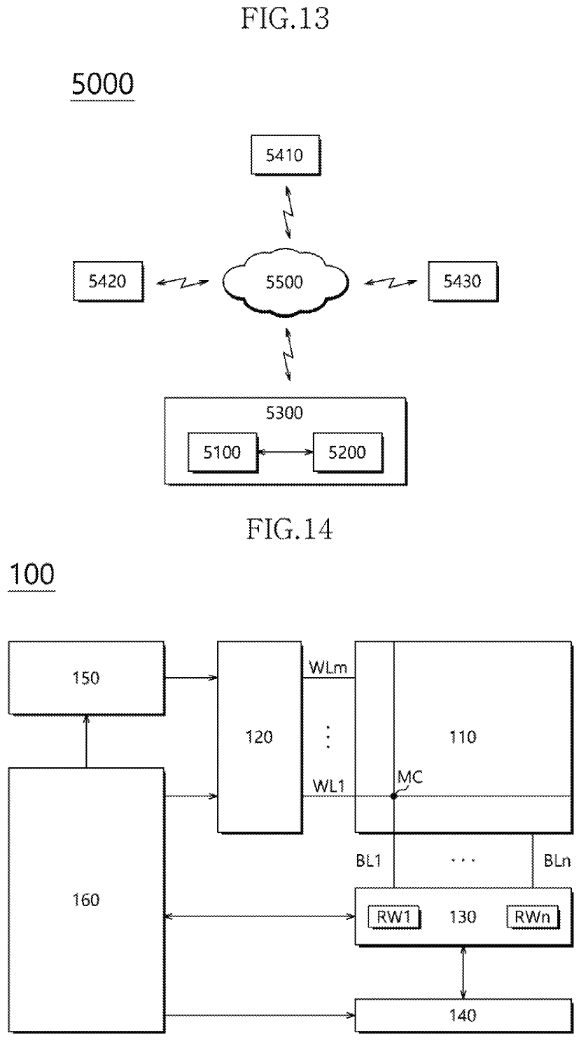

FIG. 13 is a diagram illustrating a representation of an example of a network system 5000 including a memory system 5200 according to an embodiment. Referring to FIG. 13, the network system 5000 may include a server system 5300 and a plurality of client systems 5410, 1520, and 5430 which are coupled to each other through a network 5500.

The server system 5300 may service data in response to requests from the plurality of client systems 5410 to 5430. For example, the server system 5300 may store data provided from the plurality of client systems 5410 to 5430. In another example, the server system 5300 may provide data to the plurality of client systems 5410 to 5430.

The server system 5300 may include a host 5100 and the memory system 5200. The memory system 5200 may be configured of the memory system 10 illustrated in FIG. 1, the memory system 2200 illustrated in FIG. 9, the memory system 3200 illustrated in FIG. 11 or the memory system 4200 illustrated in FIG. 12.

FIG. 14 is a block diagram illustrating the memory device 100 included in the memory system 10 according to an embodiment. Referring to FIG. 14, the memory device 100 may include the memory cell array 110, a row decoder 120, a data read/write block 130, a column decoder 140, a voltage generator 150, and a control logic 160.

The memory cell array 110 may include the memory cells MC which are arranged in regions where the word lines WL1 to WLm and the bit lines BL1 to BLn cross each other.

The row decoder 120 may be coupled with the memory cell array 110 through the word lines WL1 to WLm. The row decoder 120 may operate according to control of the control logic 160. The row decoder 120 may decode addresses provided from an external device (not shown). The row decoder 120 may select and drive the word lines WL1 to WLm, based on the decoding results. For example, the row decoder 120 may provide word line voltages provided from the voltage generator 150, to the word lines WL1 to WLm.

The data read/write block 130 may be coupled with the memory cell array 110 through the bit lines BL1 to BLn. The data read/write block 130 may include read/write circuits RW1 to RWn corresponding to the bit lines BL1 to BLn. The data read/write block 130 may operate according to control of the control logic 160. The data read/write block 130 may operate as a write driver or a sense amplifier according to an operation mode. For example, the data read/write block 130 may operate as a write driver which stores data provided from the external device, in the memory cell array 110 in a write operation. In another example, the data read/write block 130 may operate as a sense amplifier which reads out data from the memory cell array 110 in a read operation.

The column decoder 140 may operate according to control of the control logic 160. The column decoder 140 may decode addresses provided from the external device. The column decoder 140 may couple data input/output lines (or data input/output buffers) with the read/write circuits RW1 to RWn of the data read/write block 130 which respectively correspond to the bit lines BL1 to BLn, based on decoding results.

The voltage generator 150 may generate voltages to be used in internal operations of the memory device 100. The voltages generated by the voltage generator 150 may be applied to the memory cells MC of the memory cell array 110. For example, a program voltage generated in a program operation may be applied to a word line of memory cells on which the program operation is to be performed. In another example, an erase voltage generated in an erase operation may be applied to a well region of memory cells on which the erase operation is to be performed. In still another example, a read voltage generated in a read operation may be applied to a word line of memory cells on which the read operation is to be performed.

The control logic 160 may control an overall operation of the memory device 100, based on control signals provided from the external device. For example, the control logic 160 may control operations of the memory device 100 such as read, write, and erase operations of the memory device 100.

The embodiments described above are intended to illustrate and not to limit the present teachings. Various alternatives and equivalents are possible. The present teachings are not limited by the embodiments described herein. Nor are the present teachings limited to any specific type of semiconductor device. Other additions, subtractions, or modifications are possible in view of the present disclosure and are intended to fall within the scope of the appended claims.

What is claimed is:

1. A memory system comprising:
a memory device including a plurality of data storage regions; and
a controller configured to control the memory device, wherein the controller includes:
a storage region allocation module configured to allocate at least one data storage region in which write data configured as N (wherein N is a natural number of 2 or more) pieces of sub data is to be stored among the plurality of data storage regions;
a data storage reliability determination module configured to determine data storage reliability of an allocated data storage region based on process information of the memory device;
a parity management module configured to generate a parity part for the write data every M (wherein M is a natural number larger than 2 and smaller than N) pieces of sub data among the N pieces of sub data by changing the number M of pieces of sub data based on the data storage reliability; and
a control signal generation module configured to generate a control signal for controlling the memory device to store the write data and the at least one generated parity part in the allocated data storage region.

2. The memory system of claim 1, wherein the controller is further configured to receive the process information from the memory device.

3. The memory system of claim 1, wherein the process information comprises position information, and wherein the data storage reliability determination module is configured to determine the data storage reliability of the allocated data storage region based on the position information of the allocated data storage region in at least one among a wafer, a memory chip, a plane, and a block.

4. The memory system of claim 3, wherein the data storage reliability determination module is configured to determine the data storage reliability to be low when the position information indicates the allocated data storage region is disposed away from a center of the at least one among the wafer, the memory chip, the plane, and the block.

5. The memory system of claim 1, wherein when the data storage region comprises a page, wherein the data storage reliability determination module is configured to determine the data storage reliability to be different according to information on a word line coupled to the page, wherein the information indicates that the word line is located in any one of an upper portion, a central portion, and a lower portion of a block including the page.

6. The memory system of claim 1, wherein the parity management module is configured to lower the number M of pieces of sub data when the data storage reliability of the allocated data storage region is high and to increase the number M of pieces of sub data when the data storage reliability of the allocated data storage region is low.

7. The memory system of claim 1, wherein the parity management module is configured to generate the parity part by performing an exclusive OR (XOR) operation on the M pieces of sub data.

8. An operating method of a memory system comprising a memory device including a plurality of data storage regions and a controller configured to control an operation of the memory device, the method comprising:
the controller allocating at least one data storage region in which write data configured as N (wherein N is a natural number of 2 or more) pieces of sub data is to be stored among the plurality of data storage regions;
the controller determining data storage reliability of an allocated data storage region based on process information of the memory device;
the controller generating a parity part for the write data every M (wherein M is a natural number larger than 2 and smaller than N) pieces of sub data among the N pieces of sub data by changing the number M of pieces of sub data based on the data storage reliability; and
the memory device storing the write data and the at least one generated parity part in the allocated data storage region.

9. The method of claim 8, further comprising:
the controller transmitting a request for the process information to the memory device when the at least one data storage region in which the write data is to be stored is allocated; and
the memory device transmitting the process information to the controller in response to the request for the process information received from the controller,
wherein the controller determining data storage reliability includes the controller determining the data storage reliability of the allocated data storage region based on the process information received from the memory device.

10. The method of claim 8, wherein the process information comprises position information, and wherein the controller determining data storage reliability includes the controller determining the data storage reliability of the allocated data storage region based on the position information of the allocated data storage region in at least one among a wafer, a memory chip, a plane, and a block.

11. The method of claim 10, wherein the controller determining data storage reliability includes the controller determining the data storage reliability to be low when the position information indicates the allocated data storage region is disposed away from a center of the at least one among the wafer, the memory chip, the plane, and the block.

12. The method of claim 8, wherein when the allocated data storage region comprises a page, wherein the controller determining data storage reliability includes the controller determining the data storage reliability of the allocated data storage region to be different according to information on a word line coupled to the page, wherein the information indicates that the word line is located in any one of an upper portion, a central portion, and a lower portion of a block including the page.

13. The method of claim 12, wherein the generating of the parity part includes the controller changing the number M of pieces of sub data to be reduced when the data storage reliability of the allocated data storage region is high and the controller changing the number M of pieces of sub data to be increased when the data storage reliability of the allocated data storage region is low.

14. The method of claim 8, wherein the controller generating a parity part comprises the controller generating the parity part by performing an exclusive OR (XOR) operation on the M pieces of sub data.

15. A memory system comprising:
a memory device including a plurality of data storage regions; and
a controller configured to control the memory device, wherein the controller includes:
a data storage reliability determination module configured to determine data storage reliability of at least one data storage region among the plurality of data storage regions based on process information of the memory device;
a storage region allocation module configured to allocate a data storage region in which write data configured as N (wherein N is a natural number of 2 or more) pieces of sub data to be stored based on the data storage reliability;
a parity management module configured to generate a parity part for the write data every M (wherein M is a natural number larger than 2 and smaller than N) pieces of sub data among the N pieces of sub data by changing the number M of pieces of sub data based on the data storage reliability; and
a control signal generation module configured to generate a control signal for controlling an operation of the memory device to store the write data and the at least one generated parity part in the allocated data storage region.

16. An operating method of a memory system comprising a memory device including a plurality of data storage regions and a controller configured to control an operation of the memory device, the method comprising:
the controller determining data storage reliability of at least one data storage region among the plurality of data storage regions based on process information received from the memory device;
the controller allocating a data storage region in which write data configured as N (wherein N is a natural number of 2 or more) pieces of sub data is to be stored based on the data storage reliability;
the controller generating a parity part for the write data every M (wherein M is a natural number larger than 2 and smaller than N) pieces of sub data among the N pieces of sub data by changing the number M of pieces of sub data based on the data storage reliability;
the controller controlling the memory device to store the write data and the at least one generated parity part in an allocated data storage region; and
the memory device storing the write data and the at least one generated parity part in the allocated data storage region according to control of the controller.
